(19) United States
(12) Patent Application Publication
(10) Pub. No.: US 2008/0258187 A1
(43) Pub. Date: Oct. 23, 2008

(54) METHODS, SYSTEMS AND APPARATUSES FOR THE DESIGN AND USE OF IMAGER SENSORS

(76) Inventors: John W. Ladd, Boise, ID (US); Gennadiy Agranov, Boise, ID (US)

Correspondence Address: David J. Paul;Mail Stop 1-525, Micron Technology, Inc., 8000 S. Federal Way, Boise, ID, 83716, US

(21) Appl. No.: 11/736,660

(22) Filed: Apr. 18, 2007

(51) Int. Cl. H01L 31/113

(52) U.S. Cl. 257/292; 257/E31.083

(57) ABSTRACT

An imager sensor cell design having readout circuitry contained within the photodiode region.

### TECHNICAL FIELD

The present invention generally relates to methods, systems and apparatuses for the design and use of imager sensors and more specifically to imager sensors having readout circuitry embedded in a photosensor.

### BACKGROUND

In general, a circuit of an imager sensor, such as a CMOS imager sensor, includes a focal plane array of imager sensor cells (or pixels), each one of the pixels includes a photo-conversion device or photosensor, e.g., a photogate, photoconductor, or photodiode having an associated charge accumulation region within a substrate for accumulating photo-generated charge. Each pixel may include a transistor for transferring charge from the charge accumulation region to a diffusion node and a transistor for resetting the diffusion node to a predetermined charge level prior to charge transference. The pixel may also include a source follower transistor for receiving and amplifying charge from the diffusion node and an access transistor for controlling the readout of the pixel contents from the source follower transistor. In some arrangements, the transfer transistor is omitted and the charge accumulation region is coupled with the diffusion node.

In the specific case of a CMOS imager sensor cell, the active elements of a pixel perform the necessary functions of: (1) photon to charge conversion; (2) accumulation of imager charge; (3) transfer of charge to the diffusion node accompanied by charge amplification (where a transfer transistor is used); (4) resetting the diffusion node to a known state before the transfer of charge to it; (5) selection of a pixel for readout; and (6) output and amplification of a reset signal and a signal representing pixel charge from the diffusion node. The charge at the floating diffusion node is typically converted to a pixel output voltage by the source follower output transistor.

FIG. 1 depicts a conventional layout of a 2×2 pixel array segment 100 of a CMOS imager sensor device. In this general configuration the CMOS imager sensor cell 101 is set in a p+ diffusion region 102 to provide isolation between adjacent photodiode regions 104. Readout transistors 108 and transfer gates 105 are typically isolated from one another by isolation 103, i.e., shallow trench isolation (STI). CMOS imager sensor cell 101 generally comprises a transfer gate 105 for transferring photoelectric charges generated in photodiode region 104 to a diffusion region 106 acting as a sensing node, which in turn is electrically connected to the readout transistor circuitry 108. Readout circuitry 108 typically comprises an output source follower transistor, a reset transistor provided for resetting the sensing node 108 to a predetermined voltage in order to sense a next signal, and a row select transistor for outputting a signal from the source follower transistor to an output terminal in response to a pixel row select signal. This general configuration of a CMOS imager sensor cell 101 depicts a typical layout showing a conventional pixel comprising readout circuitry 108 residing outside the photodiode region 104. As indicated above, the conventional configuration of a CMOS imager sensor cell requires that the readout circuitry 108 be isolated from the photodiode, such as by using shallow trench isolation techniques, which may cause isolation defects where neighboring transistors from adjacent cells may interact with each other and the isolation allows electrons from adjacent cells to pass through and accumulate in the wrong photodiode region. The isolation between transistors and photodiode regions of individual pixel cells may be inadequate as far as eliminating electrical crosstalk between adjacent pixels, which is an area that needs addressed in the CMOS imager sensor industry.

Therefore, what is needed in the art is an imager sensor pixel design that may be integrated into an imager sensor pixel array layout design that reduces electrical crosstalk between adjacent pixels and eliminates isolation defects between adjacent readout circuitry.

### BRIEF DESCRIPTION OF THE DRAWINGS

FIG. 1 is a prior art illustration of a top-down view depicting a conventional 2×2 pixel array segment of a CMOS imager sensor device.

FIG. 2 is a top-down view of a semiconductor assembly comprising a segment of a single CMOS imager sensor cell in accordance with the present disclosure.

FIG. 3 is a top-down view of a semiconductor assembly in accordance with FIG. 2 showing a detailed representation of the photodiode contained readout circuitry of the present disclosure.

FIG. 4 is a top-down view of a semiconductor assembly depicting 2×2 pixel array segment utilizing a CMOS imager sensor cell having a photodiode contained readout circuitry arrangement of the present disclosure.

FIG. 5 is a top-down view of a semiconductor assembly depicting a CMOS imager sensor cell having a centrally located photodiode contained readout circuitry arrangement of the present disclosure.

FIG. 6 is a top-down view of a semiconductor assembly depicting a CMOS imager sensor cell having four micro-lenses in association with a centrally located photodiode contained readout circuitry arrangement of the present disclosure.

FIG. 7 is a top-down view of a semiconductor assembly depicting a CMOS imager sensor cell in a honeycomb arrangement including the photodiode contained readout circuitry arrangement of the present disclosure.

FIG. 8 is a top-down view of a semiconductor assembly depicting a CMOS imager sensor cell in a honeycomb arrangement, each cell having a micro-lens in association with a photodiode contained readout circuitry arrangement of the present disclosure.

FIG. 9 represents a system used to employ any one of the embodiments of the present disclosure.

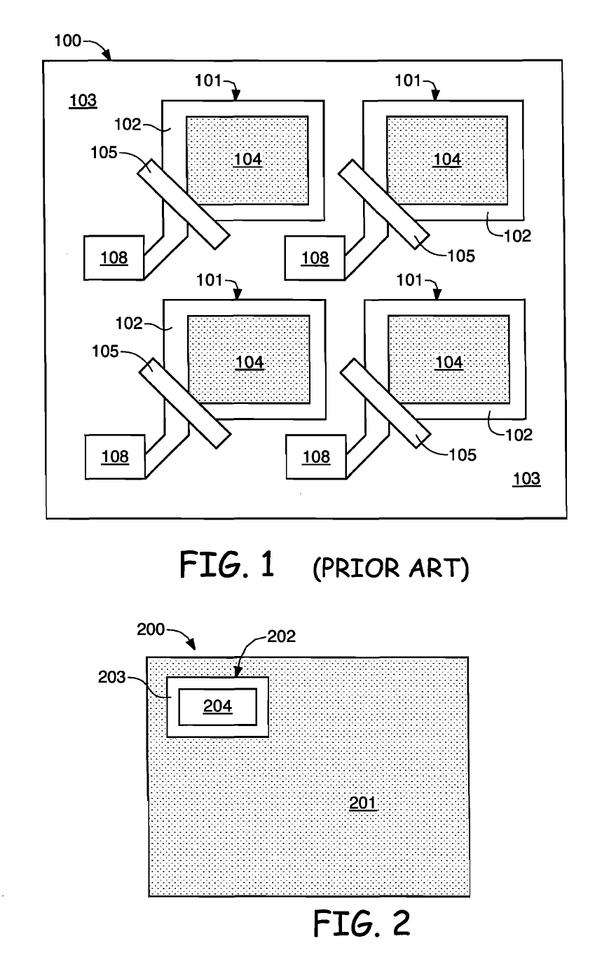

### DETAILED DESCRIPTION

In the following detailed description, reference is made to the accompanying drawings, which form a part hereof, and in which is shown by way of illustration of specific embodiments in which the invention may be practiced. These embodiments are described in sufficient detail to enable those skilled in the art to practice the invention, and it is to be understood that other embodiments may be utilized, and that structural, logical and electrical changes may be made without departing from the spirit and scope of the invention.

The terms “wafer” and “substrate” are to be understood as including silicon, silicon-on-insulator (SOI), or silicon-on-sapphire (SOS) technology, doped and undoped semiconductors, epitaxial layers of silicon supported by a base semiconductor foundation, and other semiconductor structures. In addition, the semiconductor need not be silicon-based, but could be based on other semiconductors including silicon-germanium, germanium, or gallium-arsenide. Also, the term “pixel” refers to a picture element unit cell containing a photosensor and transistors for converting electromagnetic radiation to an electrical signal.

The various embodiments of the present invention are described below in connection with CMOS processing technology for ease of explanation and are not to be considered a limitation on other types of processing technology to which the present disclosure can be applied.

Preferred embodiments of the present disclosure provide architectural array circuitry arrangements for CMOS imager sensor devices, as described below with reference to FIGS. 2-9. The top down views of each embodiment show diffusion regions and transistor gates that are components of transistors, the fabrication of which are well known and understood by those skilled in the relevant art.

A first embodiment of the present disclosure is depicted in top down views of FIGS. 2-4. FIG. 2 illustrates a CMOS imager sensor cell 200. This architectural arrangement of the CMOS imager sensor cell 200 depicts a photodiode region 201 encompassing a photodiode contained readout circuitry 202, which comprises a transfer transistor gate 202 surrounding readout transistors 204. In FIG. 2, though imager sensor cell 200 is shown is as placed in photodiode region 201, the imager sensor cell 200 may be positioned as desired within photodiode region 201 (e.g., positioning may depend on a particular desired layout of the imager sensor cell 200).

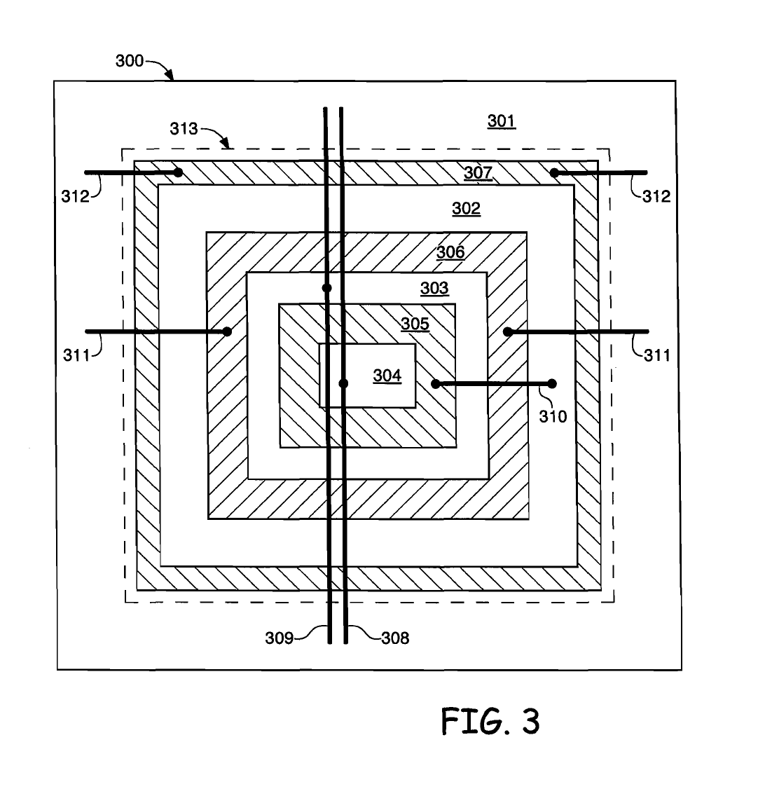

FIG. 3 illustrates a detailed representation of the photodiode region 201 encompassing the photodiode contained readout circuitry 202 of FIG. 2. Referring to FIG. 3, a photodiode contained readout circuitry 313 of the present disclosure is set in a CMOS imager sensor cell 300 (or simply referred to as a pixel) using polysilicon gates to completely enclose and electrically isolate the individual readout transistors. Referring to FIG.3, the photodiode contained readout circuitry 313 is arranged within photodiode region 301 with an outermost polysilicon gate that serves as a transfer transistor gate 307 and driven by transfer line 312 to transfer charge accumulated in the photodiode region 301 to a floating diffusion node 302, doped as n-type conductivity. Arranged inside the transfer transistor gate 307, a second encompassing polysilicon transistor gate, a reset gate 306, when driven active by reset line 311, will reset the pixel 300 by clearing the floating diffusion node 302 of any charge by allowing region 303, connected to a set voltage level by line 309, to extract electrons from floating diffusion node 302. The floating diffusion node 302 supplies a voltage level (or signal output) to a third encompassing polysilicon transistor gate, a source follower gate 305, that is connected to floating diffusion node 302 by line 310 and provides the signal output to the pixel output 304 and ultimately to pixel output bus 308.

The circuitry architectural arrangement (or layout) of FIG. 3 provides several major advantages. One advantage results from the fact that because each polysilicon transistor gate is self encompassing there is no requirement to isolate the separate transistors from the outer laying photodiode region with a dielectric material (such as by using shallow trench isolation material). In fact it is preferred that shallow trench isolation (using insulating materials such as oxides), is not used. Another advantage is that only one metal layer is required to connect the photodiode contained readout circuitry to other portions of the CMOS imager sensor device (i.e., periphery circuitry). In conjunction with using only one interconnecting metal layer, both color filters and micro-lenses can be brought closer to the silicon substrate surface, thus resulting in a smaller optical stack height. However, by having the photodiode contained readout circuitry located in the corner of the photodiode region (such as depicted in FIG. 2), a micro-lens need not be used. Instead, the photodiode contained readout circuitry and a p+ diffusion region that separates neighboring pixels will be covered with a non-transparent material (i.e., a second metal layer) to prevent light from entering these areas.

Still another advantage of having the readout circuitry contained within the pixel or sensor cell is that it is possible to shift the readout circuitry depending on the location of the pixel in the array. It is also makes it easier to design pixels with multiple pitch sizes, or a photodiode array containing pixels of various colors having different pitches, because now it is a simple matter to drop in the readout circuitry of the present disclosure into the desired pixel design. It is further anticipated that the readout circuitry 313 will provide a significant reduction in hot pixel defects as it is known that shallow trench isolation can be a large source of hot pixels. Also, it is anticipated that there can be a significant advantage in the ability of the cell to transfer charge due to the wide transfer gate geometry and noise reduction advantages of wider readout transistors.

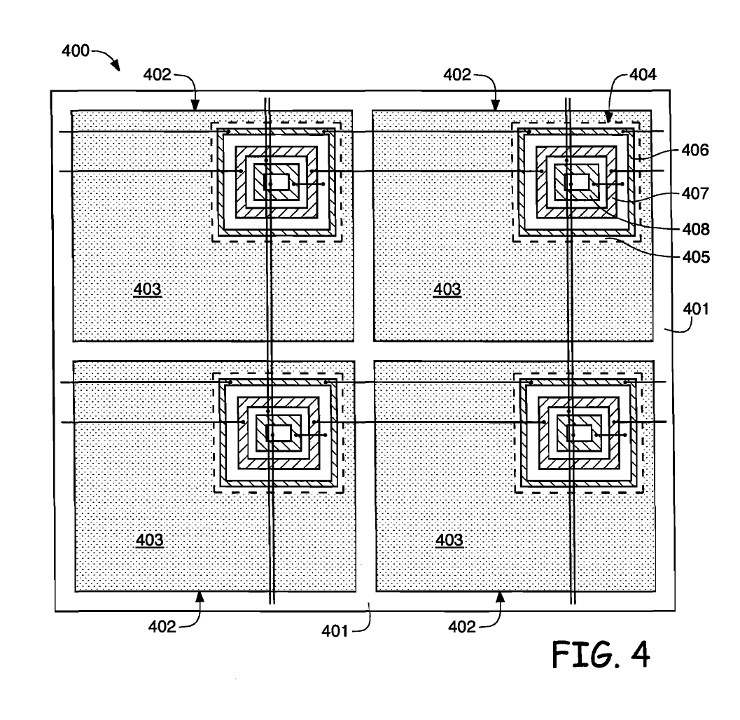

FIG. 4 depicts an example of a CMOS imager sensor pixel array 400, showing a 2×2 array segment that utilizes the photodiode contained readout circuitry CMOS imager sensor cell of FIG. 3. FIG. 4 shows a plurality of CMOS imager sensor cells 402 each cell having a photodiode contained readout circuitry 404 set within the confines of a photodiode region 403. Photodiode contained readout circuitry 404 resides in n-type diffusion 405 that comprises a transfer transistor gate 406, reset gate 407 and source follower gate 408, all of which are residing within a p+ type diffusion region 401 that underlies the entire array of CMOS imager sensor cells 402 and also isolates each individual cell from one another.

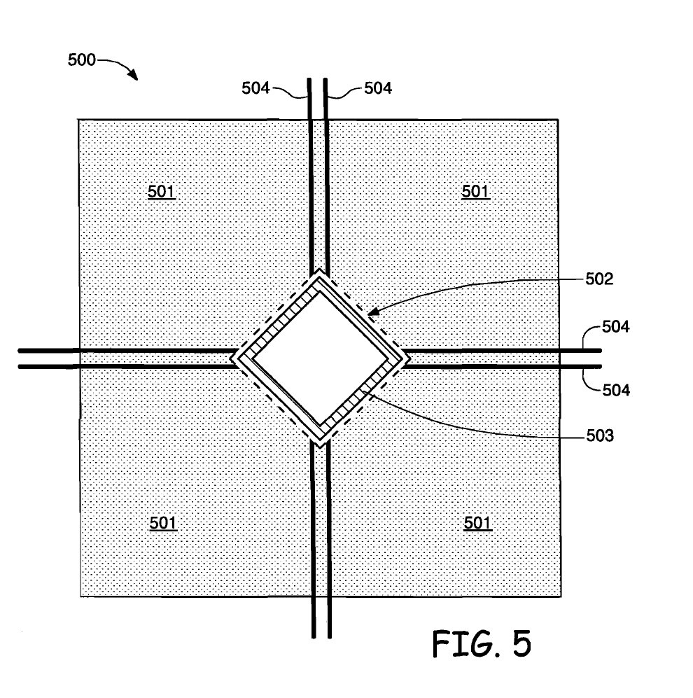

FIG. 5 depicts another embodiment of the present disclosure utilizing a similar photodiode contained readout circuitry as that discussed in FIG. 3. Referring to FIG. 5, a CMOS imager sensor cell 500 comprises photodiode region 501 which includes photodiode contained readout circuitry 502 (including transfer transistor gate 503) that preferably are centrally located within the photodiode region 501. Though it is preferred that the photodiode contained readout circuitry 502 is centrally located, processing variations may not allow perfect symmetry, thus it is to be understood that this circuitry arrangement is considered to be substantially symmetrical as to allow for processing variations. Metal buses 504 connect the photodiode contained readout circuitry 502 to periphery circuitry (not shown) of the CMOS imager sensor device. In this arrangement micro-lenses need not be used, however the photodiode contained readout circuitry and a p+ diffusion region that separates neighboring pixels will be covered with a non-transparent material (i.e., metal) to prevent light from entering these areas. If it is desired that a micro-lens be used with this arrangement, a micro-lens having a hole in the center, such as a donut shaped micro-lens that covers a major portion of photodiode region 501 and leaves a major portion of the photodiode contained readout circuitry 502 exposed and thus not covered by the micro-lens, may be utilized.

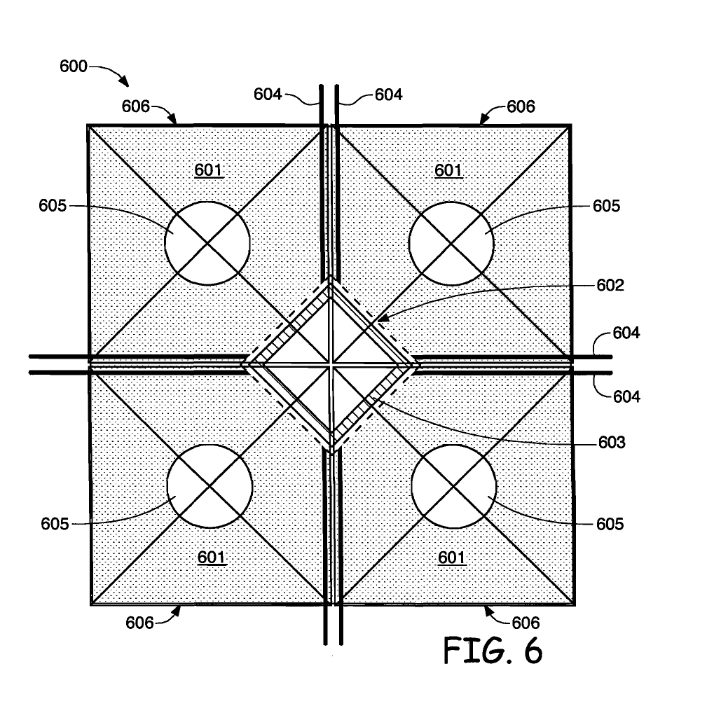

FIG. 6 depicts another embodiment of the present disclosure utilizing a similar photodiode contained readout circuitry as that discussed in FIG. 3. Referring to FIG. 6, a CMOS imager sensor cell 600 comprises photodiode region 601 which includes photodiode contained readout circuitry 602 (including a transfer transistor gate 603) that are centrally located within the photodiode region 601. Metal buses 604 connect the photodiode contained readout circuitry 602 to periphery circuitry (not shown) of the CMOS imager sensor device. In this arrangement micro-lenses 606 cover each quadrant of CMOS imager sensor cell 600 and each quadrant contains a micro-lens spot 605. The four micro-lenses 606 will effectively collect light from the entire pixel area and focus a majority of the light at the four micro-lens spots 605 on the photodiode region 601. Though it is preferred that photodiode contained readout circuitry 602 is centrally located, processing variations may not allow perfect symmetry, thus it is to be understood that this circuitry arrangement is considered to be substantially symmetrical as to allow for processing variations.

Advantages gained from the pixel layout design of FIG. 6, including the four micro-lens per pixel design, results in a higher efficiency of light collection with a relatively large size (5-10 um) comparing to a tradition 1 micro-lens per pixel design. The ease of manufacturing due to a reduction of the thickness of the micro-lens (traditionally one micro-lens pixel designs require a thicker micro-lens than the four micro-lens design that divides the imager sensor cell into four quadrants). The increased number of micro-lenses per pixel will result in a reduction of crosstalk. Also, a pixel with centrally located photodiode contained readout circuitry and four micro-lenses are preferably substantially symmetrical for angular light both from optical and electrical crosstalk standpoints and also will increase the pixel's acceptance angle of light.

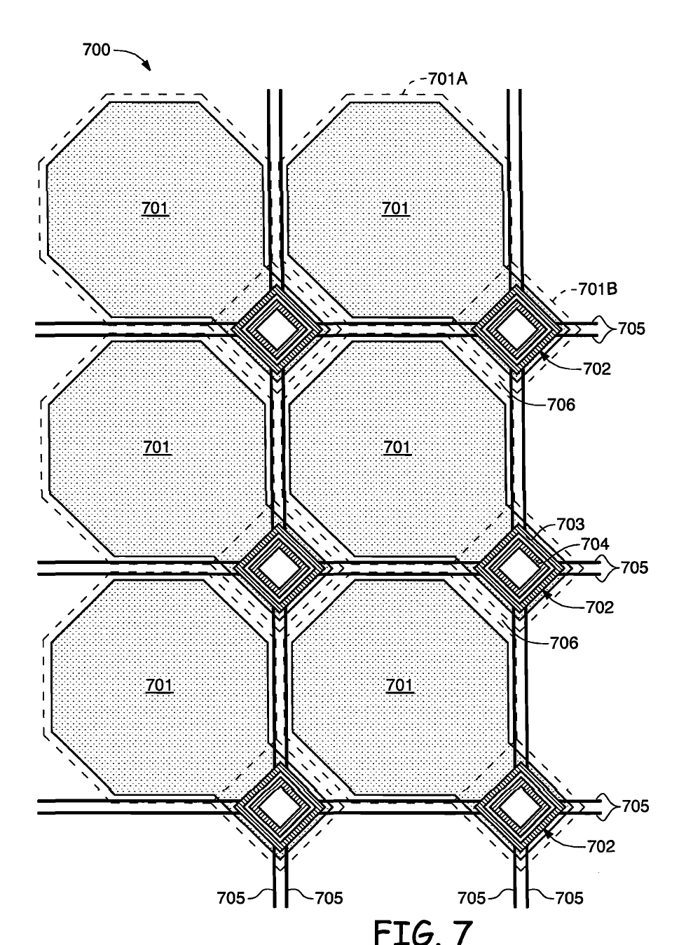

FIG. 7 depicts another embodiment of the present disclosure utilizing a similar photodiode contained readout circuitry as that discussed in FIG. 3. Referring to FIG. 7, a CMOS imager sensor device 700, showing individual imager sensor pixels 710, each comprising a photodiode region 701 and photodiode contained readout circuitry 702 in relation to the photodiode area 701 as a kind of honeycomb arrangement in that the photodiode region has a major photosensitive region in a honeycomb shape and an extending rectangular region which includes photodiode contained readout circuitry 702 (including transfer transistor gate 703). Metal buses 704 connect the photodiode contained readout circuitry 702 to periphery circuitry (not shown) of the CMOS imager sensor device 700. In this arrangement micro-lenses need not be used, however the photodiode contained readout circuitry 702 and a p+ diffusion region 705 that separates neighboring pixels will be covered with a non-transparent material (i.e., metal) to prevent light from entering these areas.

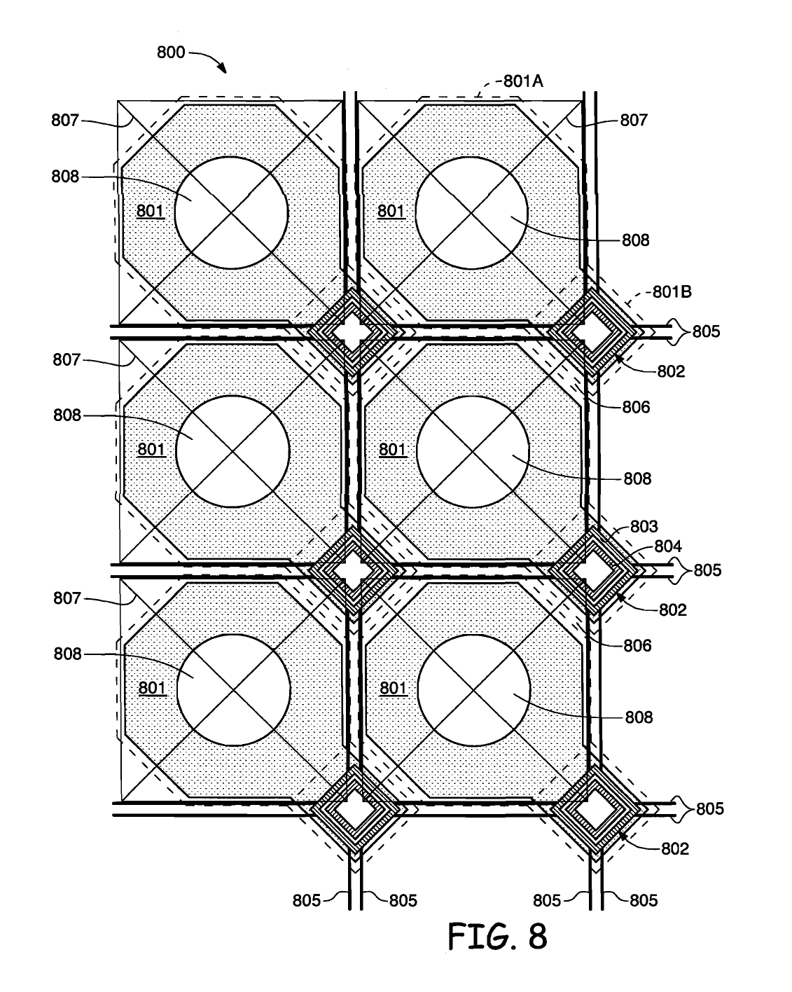

FIG. 8 depicts another embodiment of the present disclosure utilizing a similar photodiode contained readout circuitry as that discussed in FIG. 3. Referring to FIG. 8, a CMOS imager sensor device 800, showing individual imager sensor pixels 810, each comprising a photodiode region 801 that has a major photosensitive region in a honeycomb shape and an extending rectangular region which includes photodiode contained readout circuitry 802 (including transfer transistor gate 803). Metal buses 804 connect the photodiode contained readout circuitry 802 to periphery circuitry (not shown) of the CMOS imager sensor device 800. In this arrangement, a separate micro-lens 806 covers an individual pixel of CMOS imager sensor device 800. Due to the honeycomb arrangement of the photodiode region, each micron lens 806 effectively collects light onto the hexagonal shape portion of the photodiode region 801 and focuses a majority of the light to each respective micro-lens spot 807.

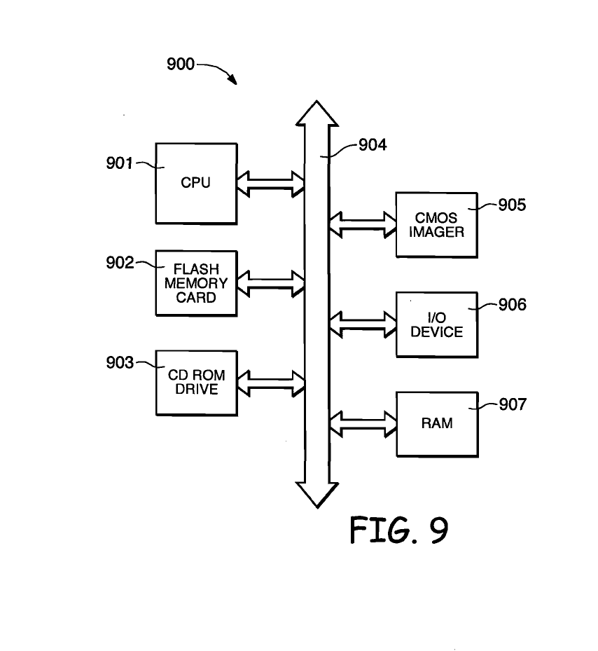

FIG. 9 depicts a processor system having digital circuits, which could include any of the CMOS imager sensor cell designs of the present disclosure. Referring to FIG. 9, a processor system 900, such as a computer system, generally comprises a central processing unit (CPU) 901, for example, a microprocessor that communicates with an input/output (I/O) device 906 over a bus 904. The CMOS imager sensor device 905 also communicates with the system over bus 904. The processor system 900 may also include random access memory (RAM) 907, and, in the case of a computer system, may include peripheral devices such as a flash memory card 902, or a compact disk (CD) ROM drive 903 which also communicate with CPU 901 over the bus 904. It may also be desirable to integrate the CPU 901, CMOS imager sensor device 905 and memory 907 on a single IC chip. Without being limiting, such a processor system could include a computer system, camera system, scanner, machine vision, vehicle navigation, video phone, surveillance system, auto focus system, star tracker system, motion detection system, imager stabilization system and data compression system for high-definition television, all of which can utilize the various embodiments of the present disclosure.

It should be noted that although the present disclosure has been described with specific reference to CMOS imager sensors having a photodiode contained readout circuitry residing in a photodiode region, the invention has broader applicability and may be used in any imaging apparatus. The above description and drawings illustrate preferred embodiments which achieve the features and advantages of the present disclosure. It is not intended that the present disclosure be limited to the illustrated embodiments and any modification thereof which comes within the spirit and scope of the following claims should be considered part of the present disclosure.

What is claimed is:

1. An imager sensor cell comprising:
a photodiode region;
readout circuitry, residing within the photodiode region comprising:
readout transistor circuitry; and
a transfer transistor having a gate that encompasses the readout transistor circuitry.

2. The imager sensor cell of claim 1, wherein the readout transistor circuitry comprises;
a reset gate to a reset transistor,
a source follower gate to a source follower transistor, the reset gate encompassing the source follower gate and the source follower gate encompassing a pixel output node.

3. The imager sensor cell of claim 2, wherein each transistor gate completely encompasses and electrically isolates the respective transistor.

4. The imager sensor cell of claim 2, wherein each transistor gate completely encloses and electrically isolates the respective transistor without the use of shallow trench isolation.

5. The imager sensor cell of claim 1 comprises a CMOS imager sensor cell.

6. An imager sensor cell comprising:
a photodiode region;
readout circuitry residing in a single quadrant region of the photodiode region.

7. The imager sensor cell of claim 6, wherein the readout transistor circuitry comprises;
a reset gate to a reset transistor, and
a source follower gate to a source follower transistor, the reset gate encompassing the source follower gate and the source follower gate encompassing a pixel output node.

8. The imager sensor cell of claim 7, wherein each transistor gate completely encompasses and electrically isolates the respective transistor.

9. The imager sensor cell of claim 7, wherein each transistor gate completely encloses and electrically isolates the respective transistor without the use of shallow trench isolation.

10. The imager sensor cell of claim 6 comprises a CMOS imager sensor cell.

11. An imager sensor cell comprising:
a photodiode region;
readout circuitry residing substantially symmetrical in the center of the photodiode region.

12. The imager sensor cell of claim 11, wherein the photodiode region is covered with a single micro-lens.

13. The imager sensor cell of claim 12, wherein the single micro-lens is donut shaped such that a major portion of the photo diode region is covered and a major portion of the transfer gate and photodiode contained readout circuitry is not cover thereby.

14. The imager sensor cell of claim 12, wherein each quadrant of the photodiode region covered with a single micro-lens will be substantially symmetrical.

15. The imager sensor cell of claim 11, wherein each quadrant of the photodiode region is covered with a single micro-lens.

16. The imager sensor cell of claim 11 comprises a CMOS imager sensor cell.

17. An imager sensor cell comprising:
a photodiode region, the photodiode region comprises a honeycomb shaped region and a rectangular region; and
readout circuitry residing in the rectangular region.

18. The imager sensor device of claim 17, wherein the readout circuitry resides in rectangular region of the photodiode region.

19. The imager sensor device of claim 17, wherein the honeycomb shaped region of the photodiode region is covered with a single micro-lens.

20. The imager sensor device of claim 19, wherein the single micro-lens covers a major portion of the honeycomb shaped region of the photodiode region but does not cover a major portion of the photodiode contained readout circuitry.

21. An imager sensor device comprising:
an array of imager sensor cells, each imager sensor cell comprising:
a photodiode region;
readout circuitry residing within the photodiode region, the readout circuitry comprising:
a transfer transistor having a gate that encompasses the readout transistor circuitry.

22. The imager sensor cell of claim 21, wherein the readout circuitry comprises:
a reset gate to a reset transistor; and
a source follower gate to a source follower transistor, the reset gate encompassing the source follower gate and the source follower gate encompassing a pixel output node.

23. The imager sensor device of claim 22, wherein the readout circuitry resides in a single quadrant region of the photodiode region.

24. The imager sensor device of claim 22, wherein the readout circuitry is arranged substantially symmetrical in the center of the photodiode region.

25. The imager sensor device of claim 22, wherein the photodiode region is covered with a single micro-lens.

26. The imager sensor device of claim 25, wherein the single micro-lens is donut shaped such that a major portion of the photo diode region is covered thereby and a major portion of photodiode contained readout circuitry is not covered thereby.

27. The imager sensor device of claim 22, wherein each quadrant of the photodiode region is covered with a single micro-lens and each micro-lens in each quadrant of the photodiode region is substantially symmetrical.

28. The imager sensor device of claim 22, wherein the photodiode region comprises a honeycomb shaped region and a rectangular region.

29. The imager sensor device of claim 28, wherein the readout circuitry resides in rectangular region of the photodiode region.

30. The imager sensor device of claim 28, wherein the honeycomb shaped region of the photodiode region is covered with a single micro-lens.

31. The imager sensor device of claim 30, wherein the single micro-lens covers a major portion of the honeycomb shaped region of the photodiode region but does not cover a major portion of the photodiode contained readout circuitry.

32. The imager sensor cell of claim 22 comprises a CMOS imager sensor cell.

33. A processor system comprising:
a processor,
an array of imager sensor cells, each imager sensor cell comprising:
a photodiode region;
readout circuitry residing within the photodiode region, the readout circuitry comprising:
a transfer transistor having a gate that encompasses the readout transistor circuitry.

34. The processor system of claim 33, wherein the readout circuitry comprises:
a reset gate to a reset transistor; and
a source follower gate to a source follower transistor, the reset gate encompassing the source follower gate and the source follower gate encompassing a pixel output node.

35. The processor system of claim 34, wherein the readout circuitry resides in a single quadrant region of the photodiode region.

36. The processor system of claim 34, wherein the readout circuitry is arranged substantially symmetrical in the center of the photodiode region.

37. The processor system of claim 34, wherein the photodiode region is covered with a single micro-lens.

38. The processor system of claim 37, wherein the single micro-lens is donut shaped such that a major portion of the photo diode region is covered thereby and a major portion of photodiode contained readout circuitry is not cover thereby.

39. The processor system of claim 34, wherein each quadrant of the photodiode region is covered with a single micro-lens and each micro-lens in each quadrant of the photodiode region is substantially symmetrical.

40. The processor system of claim 34, wherein the photodiode region comprises a honeycomb shaped region and a rectangular region.

41. The imager sensor device of claim 40 wherein the readout circuitry resides in rectangular region of the photodiode region.

42. The imager sensor device of claim 40, wherein the honeycomb shaped region of the photodiode region is covered with a single micro-lens.

43. The imager sensor device of claim 42, wherein the single micro-lens covers a major portion of the honeycomb shaped region of the photodiode region but does not cover a major portion of the photodiode contained readout circuitry.

44. The imager sensor cell of claim 34 comprises a CMOS imager sensor cell.
